(19) United States
(12) Patent Application Publication
(10) Pub. No.: US 2009/0207568 A1
(43) Pub. Date: Aug. 20, 2009

(54) METHOD AND APPARATUS FOR COOLING IN MINIATURIZED ELECTRONICS

(76) Inventor: Heikki Antti Mikael Haveri, Palakoskentie (FI)

Correspondence Address: DEAN D. SMALL;THE SMALL PATENT LAW GROUP LLP, 225 S. MERAMEC, STE. 725T, ST. LOUIS, MO, 63105, US

(21) Appl. No.: 12/032,940

(22) Filed: Feb. 18, 2008

(51) Int. Cl. H05K 7/20

(52) U.S. Cl. 361/699

(57) ABSTRACT

A method and apparatus for cooling in miniaturized electronics are provided including in an electronic circuit board. The electronic circuit includes a substrate and at least one integrated channel within the substrate configured to allow fluid flow therethrough.

### BACKGROUND OF THE INVENTION

One or more embodiments of this invention relate generally to a method and apparatus for cooling miniaturized electronics, and more particularly, to electronic circuit boards having integrated cooling channels.

As electronic devices are miniaturized, the amount of heat generated by the more densely populated electronics increases. As the amount of generated heat increases, the components within the device also operate at higher temperatures. These higher temperatures can degrade the performance of the devices. Moreover, the increased heat also emanates from the device. Accordingly, in some applications, for example, in medical ultrasound imaging probes that contact individuals during an exam, the increased heat not only can cause injury, but may exceeded acceptable regulatory levels. Accordingly, these devices have to be cooled.

In the medical imaging area, and particularly, in the ultrasound imaging area, heat is often a serious problem as a result of the intense processing that has to be performed at the scan head of the ultrasound probe. The dissipated heat from the scan head (e.g., from the miniaturized electronics in the scan head) needs to be transferred away from the scan head both to ensure the safety of the individual being scanned and to comply with certain regulatory guidelines to maximum heating conditions, which are especially critical when performing obstetrical scans. Additionally, increased heating of the scan head can affect the useful life of the ultrasound probe.

Current methods to dissipate the heat in devices with miniaturized electronics typically include heat sinks or heat exchangers that are complex, large and heavy. Thus, the reduced sized advantage gained from the miniaturized electronics is offset by the heat dissipation components that are needed. These current heat dissipation methods also add time and cost to manufacturing and maintenance, as well as result in a device that is often more cumbersome to use. For example, in ultrasound imaging systems (e.g., 4D ultrasound imaging systems), FR-4 (Flame Retardant 4) material is often used to manufacture the printed circuit boards within the probes of these systems. The processors and miniaturized components on these printed circuit boards generate heat that must be dissipated. Known cooling designs include an aluminum housing with machined fluid channels that are glued to the processor with the channels positioned adjacent the printed circuit boards. Fluid is pumped through the channels to dissipate the heat emanating from the adjacent printed circuit boards. The housing also may be covered in copper tape in an attempt to remove the heat from the housing. As a result of having to use the housing with channels, the overall device size and weight is increased, which affects the portability and potential applications for the ultrasound system. Also, the device is often time consuming to manufacture because the manufacturing steps have to be performed by hand.

### BRIEF DESCRIPTION OF THE INVENTION

In one embodiment, an electronic circuit board is provided. The electronic circuit includes a substrate and at least one integrated channel within the substrate configured to allow fluid flow therethrough.

In another embodiment, an electronic system having integrated cooling is provided. The electronic system includes a plurality of electronic circuit boards each having at least one cavity formed therein. The electronic system further includes at least one inlet port and at least one outlet port together configured to provide access to the at least one cavity in each of the plurality of circuit boards.

In yet another embodiment, a method for dissipating heat in an electronic circuit board is provided. The method includes forming at least one integrated channel within the electronic circuit board. The method further includes providing access to the integrated channel from outside the electronic circuit board to allow fluid flow through the integrated channel.

### BRIEF DESCRIPTION OF THE DRAWINGS

FIG. 1 is a top perspective view of an electronic circuit board formed in accordance with various embodiments of the invention showing an integrated channel in phantom lines.

FIG. 2 is a cross-sectional view of the electronic circuit board shown in FIG. 1.

FIG. 3 is an exploded view of a multilayer circuit structure formed in accordance with various embodiments of the invention.

FIG. 4 is a cross-sectional view of the multilayer circuit structure of FIG. 3 taken along the line 4-4 and showing cavities and volumes therein.

FIG. 5 shows one arrangement for a cavity that can be formed in the multilayer circuit structure of FIG. 3.

FIG. 6 shows another arrangement for a cavity that can be formed in the multilayer circuit structure of FIG. 3.

FIG. 7 shows another arrangement for a cavity that can be formed in the multilayer circuit structure of FIG. 3.

FIG. 8 is a perspective view of multiple electronic circuit boards constructed in accordance with various embodiments of the invention connected to tubing for circulating fluid through cavities of the electronic circuit boards.

FIG. 9 is a block diagram of an ultrasound system having electronic circuit boards that are formed in accordance with various embodiments of the invention.

FIG. 10 is a block diagram of an ultrasound probe in communication with a host system for use with the ultrasound system shown in FIG. 9 and having electronic circuit boards that are formed in accordance with various embodiments of the invention.

### DETAILED DESCRIPTION OF THE INVENTION

The foregoing summary, as well as the following detailed description of certain embodiments of the present invention, will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors or memories) may be implemented in a single piece of hardware (e.g., a general purpose signal processor or random access memory, hard disk, or the like). Similarly, the programs may be stand alone programs, may be incorporated as subroutines in an operating system, may be functions in an installed software package, and the like. It should be understood that the various embodiments are not limited to the arrangements and instrumentality shown in the drawings.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

Various embodiments of the invention provide an electronic circuit board with integrated cooling, and more particularly, integrated cooling channels within or along the electronic circuit board to allow the passage therethrough of a fluid. The flow of fluid through one or more channels dissipates heat and transfers the heat away from the electronics associated with the circuit board. It should be noted that when reference is made herein to fluid, this is not limited to liquid or any type of liquid, but can include, for example, air, gas, oil, etc. In general, the fluid is any type of substance that can flow through the integrated cooling channels to provide a cooling effect. The fluid may be selected based on the particular application. For example, an electronics cooling liquid may be used to cool electronics.

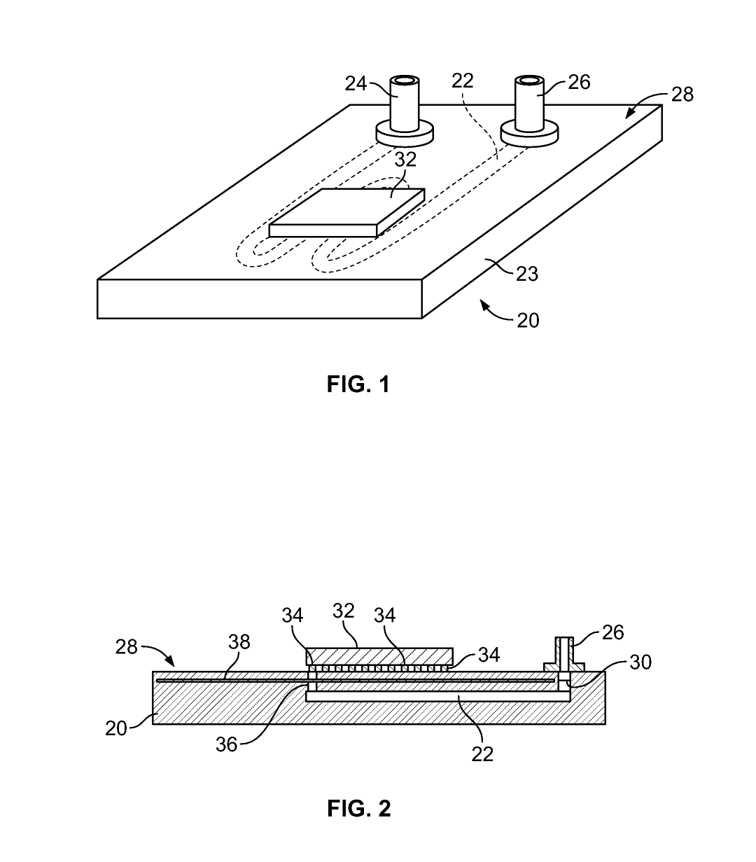

FIGS. 1 and 2 show an electronic circuit board 20 formed in accordance with various embodiments of the invention having one or more integrated channels 22 that allow the passage of fluid therethrough. The integrated channels 22 may be formed in or along the electronic circuit board 20 (defined by a substrate 23) in different configurations, sizes and orientations. An input port 24 and an output port 26 are also provided to allow access to the integrated channels 22. In particular, the input port 24 and output port 26 are each provided on a surface of the electronic circuit board 20, for example, a top surface 28 and configured to allow access to the integrated channels 22. For example, the input port 24 and output port 26 allow fluid to flow from the input port 24 through the integrated passage 22 and out the output port 26. In the various embodiments, vias 30 corresponding to each of the input port 24 and output port 26 connect the input port 24 and output port 26 to different ends of the integrated channel 22. The vias 30 essentially extend from the top surface 28 of the electronic circuit board 20 into the electronic circuit board 20 and to the integrated channel 22.

It should be noted that although FIGS. 1 and 2 illustrate only a single integrated channel 22, more than one integrated channel 22 may be formed within or along the electronic circuit board 20. Each integrated channel 22 may have a separate input port 24 and output port 26 or more than one integrated channel 22 may have the same input port 24 and output port 26. Additionally, multiple integrated channels 22 may interconnect within the electronic circuit board 20.

In the various embodiments, the integrated channel 22 and the vias 30 may be cavities formed within the electronic circuit board 20. The passage of fluid (e.g., a cooling fluid) through the integrated channel 22 provides for the dissipation of heat away from one or more electronic components 32 connected to the top surface 28 of the electronic circuit board 20. The one or more electronic components 32 may be, for example, an integrated circuit chip or other processing chip that includes a plurality of pins 34 for connection to the electronic circuit board 20 in any known manner. The plurality of pins 34 in various embodiments are, for example, straight metallic pins, which may connect to other circuit connections, such as through bonded wires. One or more of the plurality of pins 34 optionally may be thermally connected to the channel 22 via a thermal via 36. The thermal via 36 essentially extends from the one or more of the plurality of pins 36 into the electronic circuit board 20 to the channel 22. However, it should be noted that the thermal via in the various embodiments is a metal filled via that extends into the electronic circuit board 20 and ends adjacent to the integrated channel 22 without extending into the integrated channel 22.

In operation, the one or more components 22 can be cooled (e.g., heat dissipated from the one or more components 22) by conducting temperature through one or more component pins 34 connected to thermal via 34 and that further connects to the integrated channel 22 below the one or more electronic components 32. The thermal via 36 may be formed, for example, of a thermally conductive (and optionally an electrically conductive) metal material, such as silver, platinum or a similar material that provides thermal conduction through the integrated channel 32 and optionally also electrical connection of the electronic component 32 to an electrical layer 38 of the electronic circuit board 20. For example, the electrical layer 38 may include or be connected to embedded electrical components, such as resistors, inductors, capacitors, etc. Temperature conducted into the integrated channel 22 can be further transferred outside the electronic circuit board 20 within a fluid flowing by the thermal via 36 through the integrated channel 22 from the input port 24 to the output port 26. Accordingly, heat may be dissipated from otherwise large and complex systems miniaturized into a small, mass producible assembly.

The integrated channels 22 within the electronic circuit board 20 of the various embodiments may be formed, for example, as cavities between a top layer and bottom layer of a multilayer structure as described in more detail below. In general, cavities and/or holes may be cut using a laser or other suitable cutting device at different layers of the multi-layer structure that are then combined and laminated. In various embodiments, the electronic circuit board 20 with the one or more integrated channels 22 is formed using a Low Temperature Co-fired Ceramics (LTCC) process. The LTCC process allows, for example, for the ceramic material forming the multiple layers of the electronic circuit board 20 to be fired with (i.e., co-fired) with conductive materials (e.g., silver, gold, copper, platinum, etc.), such as at a temperature of 900 degrees Celsius. The LTCC process also allows the embedding of passive electronic components, such as resistors, inductors, capacitors, etc. into the electronic circuit board 20. The electronic circuit board 20 formed form the LTCC process allows, for example, for the mass production of dimensionally accurate, inexpensive, very small, but highly integrated electronic circuit boards including wire bonded devices such as processors, PGAs, paste resistors, buried capacitors etc. processed in a standard process. Thus, more circuits can be packed into a much smaller volume with the integrated channel 22 dissipating the heat generated by the electronics of the electronic circuit board 20. It should be noted that the electronic circuit board 20 of the various embodiments is not limited to an LTCC structure, but may be formed by any suitable process that allows channels 22 to be integrated within or along the electronic circuit board 20.

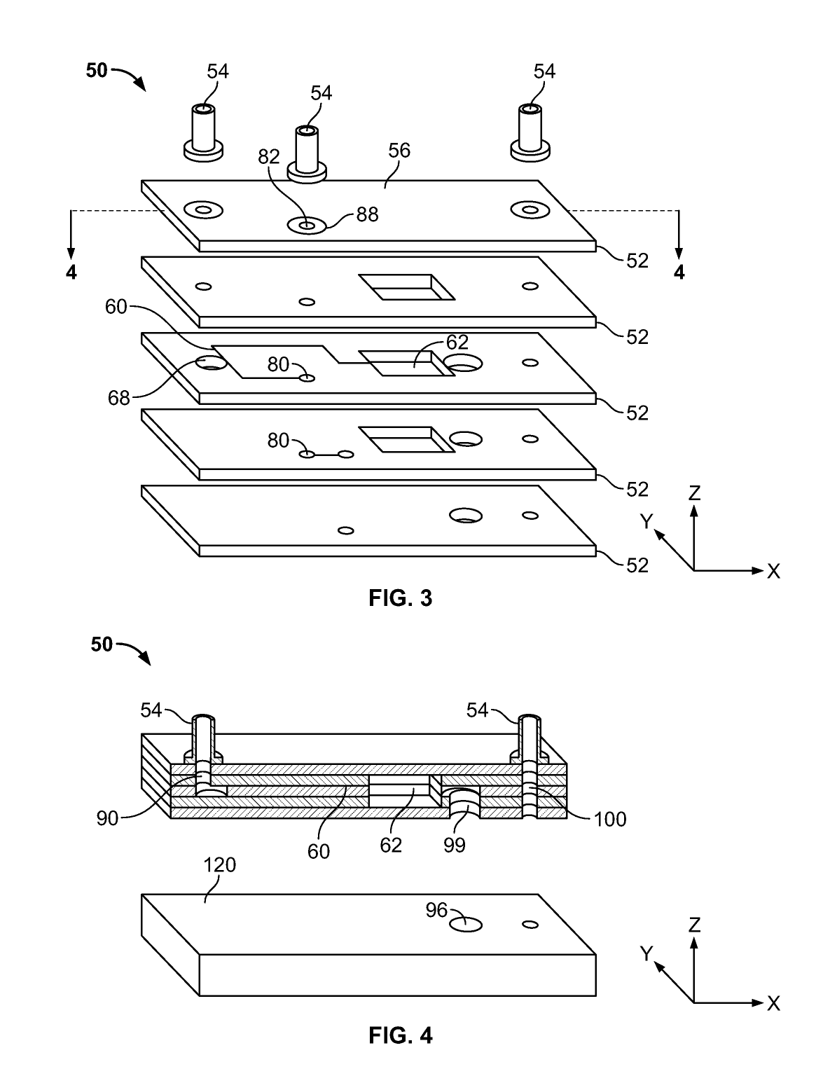

It also should be noted that the electronic circuit board 20 formed, for example, from the LTCC process can be made up of a plurality of layers, such as forty layers, with cavities defining the channels 22 formed in one or several of the layers. FIG. 3 illustrates a multilayer LTCC circuit 50 in exploded view that may be used to form the electronic circuit board 20. The multilayer LTCC circuit 50 may be formed from glass-ceramic sheets, also referred to as greensheets. FIG. 3 shows the greensheets before the layers formed by the greensheets are laminated, fired and before any electronic components 32, for example, Surface Mounted Devices (SMDs), are mounted on the electronic circuit board 20. FIG. 4 shows a cross-sectional view of the multilayer LTCC circuit 50 along the line 4-4 of FIG. 3 after the greensheets have been processed to form, for example, the electronic circuit board 20. The multilayer LTCC circuit 50 is shown having five layers 52 formed, for example, from greensheets. Surface mounted devices, and in particular, ports 54, such as inlet and outlet ports that may form one or more of the input port 24 and output port 26 (shown in FIGS. 1 and 2) are placed on a top surface 56 of the structure. However, it should be noted that the SMDs are not limited to the ports 56, but may be electronic components (e.g., the electronic component 32 shown in FIGS. 1 and 2) or similar devices.

Each of the layers 52 has a thickness based on, for example, the greensheet from which the layer 52 is formed. In general, the layer 52 may have a thickness of between approximately 50 micrometers (μm) and approximately 400 μm. It should be noted that the maximum number of greensheets that can be used to implement the multilayer LTCC circuit 50 depends on the size of the substrate plane area and the thickness of greensheets used. For example, a smaller plane area and higher layer thickness decreases the number of layers 52 that can be used because the lamination becomes more difficult as the multilayer LTCC circuit 52 tends to collapse during the manufacturing process. However, it should be noted that in the various embodiments, the multilayer LTCC circuit 50 forming the electronic circuit board 20 having one or more integrated channels 22 may include more than forty layers 52. However, the multilayer LTCC circuit 50 also may include less than the five layers 52 shown. The height of the multilayer LTCC circuit 50 may be several millimeters.

Using the LTCC process, multiple single greensheets (e.g., unfired tapes used to form one layer 52 of the multilayer LTCC circuit 50), with printed low resistivity conductor lines etc. on the surface of each other may be fired all together in one step. Passive elements such as resistors, inductors, capacitors, etc. may be embedded into the substrate, which reduces circuit dimensions.

As can be seen in FIG. 4, cavities 60 or volumes 62 (that will define, for example, the one or more integrated channels 22) are processed into the different layers 52, for example, into the different greensheets by cutting openings or slots within the layers 52. The cutting may be provided, for example, with a laser, puncher or similar device into a direction generally perpendicular to the XY plane of the layers 52. After layers 52, which may be greensheets, are laminated, the cavities 60 and volumes 62 are formed between the planar surfaces of the layers 52. For example, the cavities 60 or volumes 62 may be formed from two layers 52, one above and one below the formed cavity 60 or volume 62. The cross-sectional shape of the cavities 60 or volumes 62 is thus approximately a rectangle (or other shape, such as a cylinder) in the direction of the cavity 60 in the XZ plane or YZ plane of the layers 52.

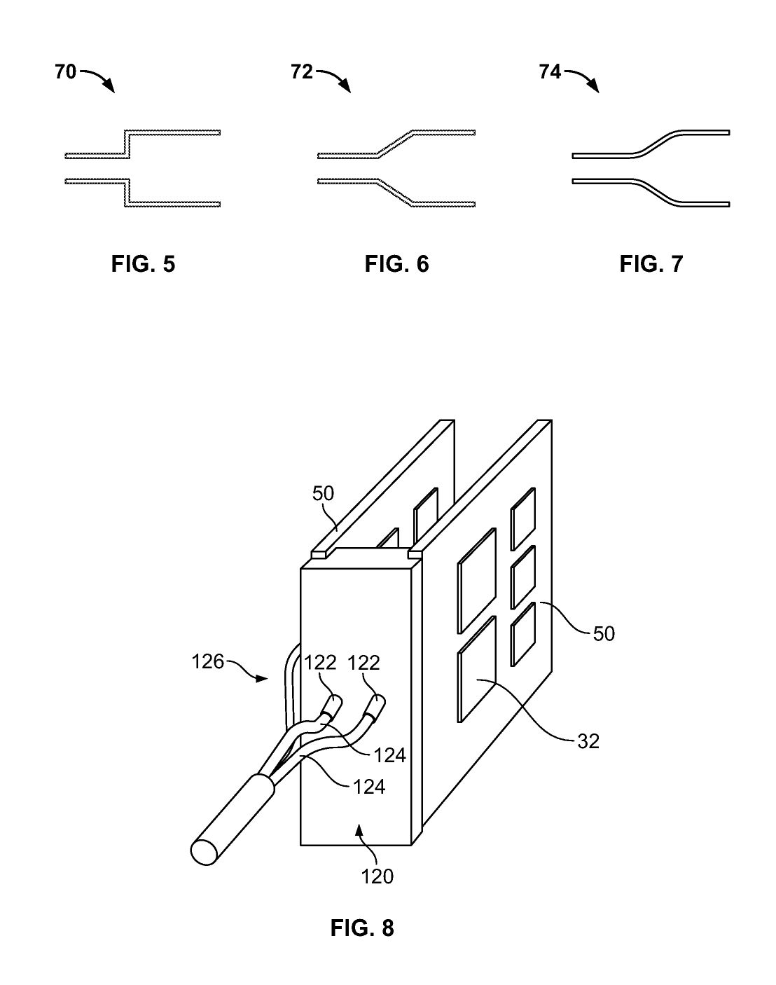

It should be noted that the width of the cavity 60 or volume 62 in the XY plane can vary approximately from tens of micrometers to several millimeters. Also, the width of the cavity 60 or volume 62 can be varied, such that different configurations may be provided. For example, a step like shaped arrangement 70 with step like increments (or decrements) may be provided as shown in FIG. 5. As another example, and as shown in FIG. 6, a conical shaped arrangement 72 may be provided. As still another example, a continuously changing width arrangement 74 as shown in FIG. 7 may be provided. However, it should be noted that cavity 60 or volume 62 are not limited to these arrangements, but may be shaped and sized as desired or needed by modifying the cutting of the openings or slots into the different layers 52. For example, the width of the cavity 60 is defined by the cutting width of the tooling used to perform the cut in, for example, the greensheets, as well as the fabrication process. It should be noted that during the lamination process, which may be provided using any known process, the cavities 60 and volumes 62 in different layers 52 formed by the greensheets may be filled or partially filled with material that support or hold up the cavities 60 and volumes 62 to resist or prevent collapse. The filling material is then burned off during firing as is known.

The height of the cavity 60 or volume 62 in the direction of the Z axes is defined by the thickness of the layers 52 and the number of layers 52 (e.g., greensheets) used to form the cavity 60 or volume 62. The minimum height of the cavity 60 or volume 62 is defined by the minimum thickness of a single layer 52 (e.g., the thickness of a single greensheet). The maximum height of the cavity 60 or volume 62 may be, for example, several millimeters, as formed by multiple layers 52. It should be noted that the height of the cavity 60 or volume 62 increases or decreases in increments or decrements based on the thickness of each of the layers 52.

The length of the cavity 60 or volume 62 can be varied, for example, from a few micrometers to hundreds of millimeters. It should be noted that is the designed cavity 60 is complicated (e.g., complex turns, etc.), lamination can become more difficult as the two halves that the cavity 60 divides can move relative to each other. The cavities 60 and volumes 62 can have different shapes and forms in the XY plane of the layers 52 and can be multi-directional as each cavity 60 or volume 62 can be divided into several different cavities 60, for example, as shown at point 68 in FIG. 6. The cavities 60 or volumes 62 also may join into a single common cavity 60 or volume 62. The cavities 60 can turn in different directions within or between layers 52, for example, in any circular or sharp angle in the direction of a plane and right angle when the cavity 60 shifts to another plane. Different cavities 60 in adjacent layers can be connected to each other by positioning the cavities 60 to overlap as shown by the connection 80 in FIG. 3. The cavities 60 that are in different, but non-adjacent layers 52, can be connected through vias. For example, the via 82, which is formed from perforations or openings through one or more layers 52, is also processed into different layers 52, for example, by cutting the perforations or openings into greensheets using a laser, a puncher or by drilling into a direction perpendicular to the XY plane of the greensheets.

The cross-sectional shape of the via 82 in the direction perpendicular to the XY plane are normally made circular. However, the cross-sectional shape may be other than circular, for example, oval, square, rectangular, etc. The via 82 may be filled with electrically conducting material, such as silver etc. and used for connecting electrically different conductor lines and electrical layers to each other (as described herein), or to connect cavities 60 to each other that are in different, but non-adjacent layers 52. Similarly the via 82 can be used to connect cavities from outside the multilayer LTCC circuit 50 through the planar surfaces as shown by the connection 90 in FIG. 4. It is also possible to connect to cavities 60 from outside the multilayer LTCC circuit 50 through the edges of the structure (not shown). Also, tubular or any other shape of cavities 100 may be formed through a via perforating one, several or all the layers 52 in a direction perpendicular to the XY plane of the layers 52. Further, vias that are filled with thermally conductive material such as silver etc., can further be used together with thermally conductive conductor lines and planes to conduct and transfer heat from, for example, electrical circuitry, such as the electronic component 32 into fluid flowing in integrated channel 22 (both shown in FIGS. 1 and 2).

The connections outside the multilayer LTCC circuit 50, including, for example, the ports 54 may be mounted on the topmost layer 52 by gluing or soldering into a metallization 88 on the surface of the topmost layer 52 around the via 82. Cavities 60 can then be coupled to other systems through tubing or a similar connection to the ports 54 as described herein. Optionally, the multilayer LTCC circuit 50 may be connected to another system (e.g., another multilayer LTCC circuit 50 or interface or base) by a connection 94 (configured as a via) on a bottom layer of the multilayer LTCC circuit 50 directly to a similar connection 96 on the surface of, for example, a plastic interface 120 as shown in FIG. 4. The connection may be made by gluing or similarly attaching the two adjacent surfaces together such that the opposite openings abut each other to form a continuous channel.

Thus, as shown in FIG. 8, cavities 60 from multiple multilayer LTCC circuits 50 (e.g., two or more electronic circuit boards 20 formed from the multilayer LTCC circuits 50) may be connected through the interface 120 (e.g., plastic base), which also contains cavities for board to board connection. The interface 120 also includes ports 122 (e.g., an inlet an outlet port) to connect to tubing 124, such as plastic or rubber tubing, which is connected to a pump (not shown) or other structure that circulates fluid through the cavities 60 and volumes 62 (as well as the vias) shown in FIGS. 3 and 4 that may define the integrated channel 22 shown in FIGS. 1 and 2. An electrical cable 126 or other electrical connection also may be provided and connected to one or both of the multilayer LTCC circuits 50. The electrical cable 126 may be provided as part of a cable assembly with the tubing 124. The interface 120 may connect to each of the multilayer LTCC circuits 50 by gluing or other means such that openings on adjacent surfaces of the interface 120 and one or both of the multilayer LTCC circuits 50 abut or overlap to form a continuous fluid channel from and to the pump through the tubing 124. It should be noted that the multilayer LTCC circuits 50 may be connected in series or parallel. In a series connection arrangement, a plastic or rubber tube may connect each of the multilayer LTCC circuits 50.

The tubing 124 may be connected directly to, for example, the input port 24 and output port 26 of the electronic circuit board 20 (shown in FIGS. 1 and 2) to circulate fluid through the integrated channel 22, which may be formed by the cavities 60 or volumes 62 of the multilayer LTCC circuit 50 (as described above), which forms the electronic circuit board 20.

Thus, the integrated channel 22 that may be defined by the cavities 60 and/or volumes 62 allows fluid flow through the electronic circuit board 22 formed from, for example, the multilayer LTCC circuit 50, to dissipate heat. The cavities 60 and/or volumes 62 optionally can be further connected to sensing devices such as pressure sensors integrated into the multilayer LTCC circuit 50 that also contains electrical circuitry. Additional components also may be included as described herein and the whole system tested in an automated process. As a last step of fabrication, larger circuits may be cut apart to form finished multilayer LTCC circuits 50 defining different electronic circuit boards 20.

It should be noted that although the various embodiments are described below in connection with an ultrasound system, the various embodiments are not limited to ultrasound systems or diagnostic imaging systems. The various embodiments may be implemented as part of or in any system where cooling of electronics is desired or needed. For example, the various embodiments may be used to cool any type of processor, electronic processing device, processing machine, etc. such as the processors or integrated circuits associated with a personal computer (PC) system.

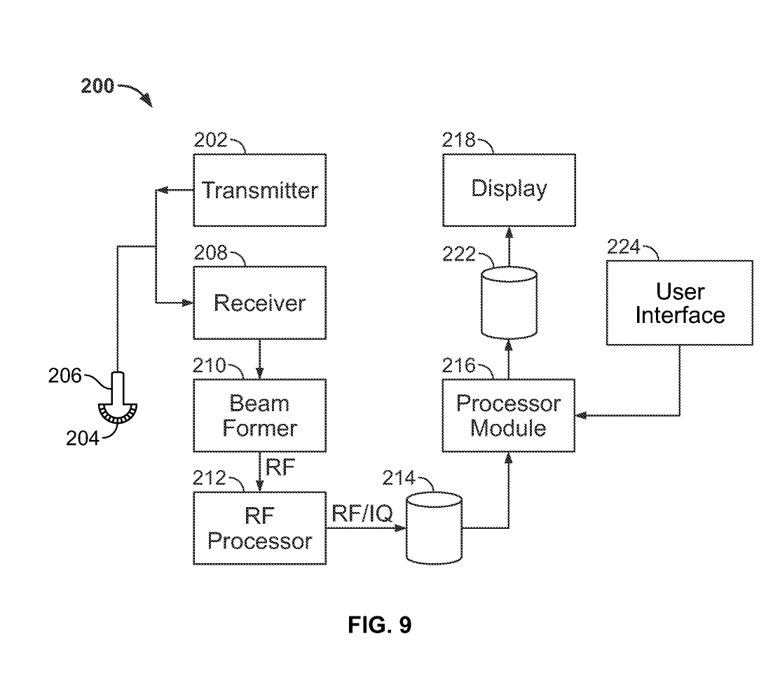

At least one technical effect of the various embodiments is dissipating heat in an electrical circuit board by integrating therein channels that allow fluid flow therethrough. It should be noted that the various embodiments may be used in any application wherein heat dissipation or heat transfer from electronic devices is needed. For example, the various embodiments may be used in connection with the electronics associated with a probe having a transducer 206 (or transducer array) in an ultrasound system 200 as shown in FIG. 9. The ultrasound system 200 includes a transmitter 202 that drives an array of elements 204 (e.g., piezoelectric elements) within a transducer 206 to emit pulsed ultrasonic signals into a body. The elements 204 may be arranged, for example, in one or two dimensions. A variety of geometries may be used. The ultrasonic signals are back-scattered from structures in the body, like fatty tissue or muscular tissue, to produce echoes that return to the elements 204. The echoes are received by a receiver 208. The received echoes are passed through a beamformer 210 that performs beamforming and outputs an RF signal. The RF signal then passes through an RF processor 212. Alternatively, the RF processor 212 may include a complex demodulator (not shown) that demodulates the RF signal to form IQ data pairs representative of the echo signals. The RF or IQ signal data may then be routed directly to a memory 214 for storage.

The ultrasound system 200 also includes a processor module 216 to process the acquired ultrasound information (e.g., RF signal data or IQ data pairs) and prepare frames of ultrasound information for display on display 218. The processor module 216 is adapted to perform one or more processing operations according to a plurality of selectable ultrasound modalities on the acquired ultrasound information. Acquired ultrasound information may be processed and displayed in real-time during a scanning session as the echo signals are received. Additionally or alternatively, the ultrasound information may be stored temporarily in memory 214 or memory 222 during a scanning session and then processed and displayed in an off-line operation.

A user interface 224 may be used to input data into the system 200 and to adjust settings and control operation of the processor module 216. One or both of memory 214 and memory 222 may store two-dimensional (2D) and/or three-dimensional (3D) datasets of the ultrasound data, where such datasets are accessed to present 2D and/or 3D images. Multiple consecutive 3D datasets may also be acquired and stored over time, such as to provide real-time 3D or four-dimensional (4D) display. The images may be modified and the display settings of the display 218 also manually adjusted using the user interface 224.

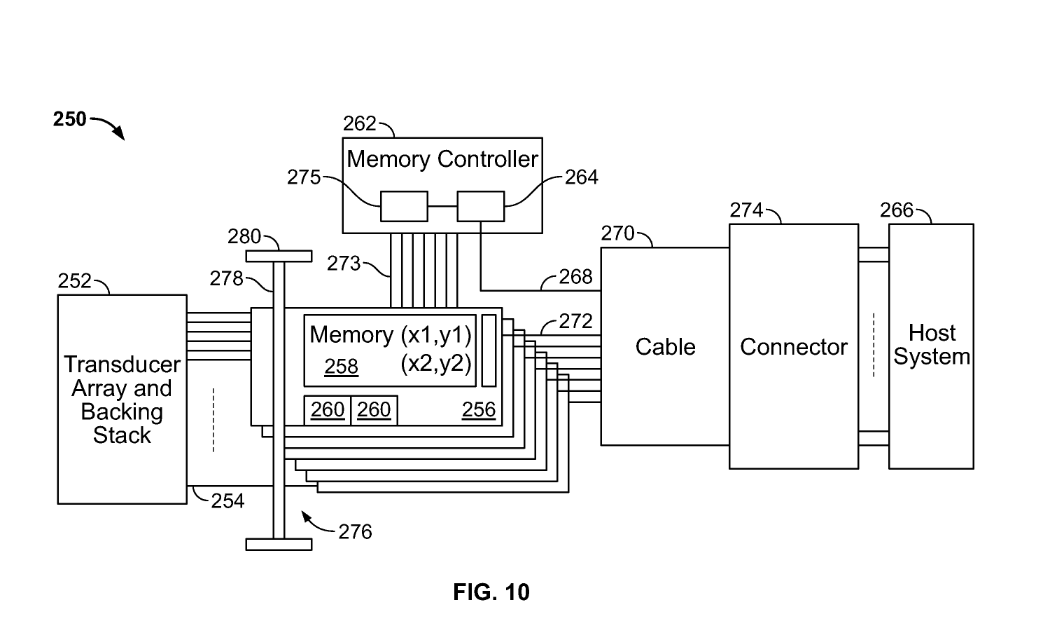

In particular, the various embodiments of the invention may be implemented as part of the electronics of an ultrasound probe 250 shown in FIG. 10 that may be used in connection with the ultrasound systems 200. The ultrasound probe 250 includes a transducer array and backing stack 252 (the “transducer array 252”), transducer flex cables 254, which may be formed as a scan head cable, and multiple processing boards 256 that support processing electronics and formed with integrated channels (shown in FIGS. 1 and 2). Each processing board 256 may includes a location memory 258 (which may include geometry RAM, encoder RAM, location registers and control registers as noted below) and signal processors 260. A location memory controller 262 (e.g., a general purpose CPU, microcontroller, PLD, or the like) also may be provided and includes a communication interface 264.

The communication interface 264 establishes data exchange with a host system 266 over communication lines 268 (e.g., digital signal lines) and through a system cable 270. Additionally, in an exemplary embodiment, the system cable 270 includes coaxial cables 272 that connect to the processing boards 256 to communicate transmit pulse waveforms to the transducer array 252 and communicate receive signals, after beamforming, to the host system 266. The probe 250 also may include a connector 274, through which the probe 250 connects to the host system 266.

A clamp 276 may be provided to hold the transducer flex cables 254 against the processing boards 256. The clamp 276 thereby aids in establishing electrical connectivity between the transducer flex cables 254 and the processing boards 256. The clamp 276 may include a dowel pin 278 and a bolt 280, although other implementations are also suitable.

For every ultrasound beam, the location memory controller 262 connects via digital signal lines 273 (e.g., carried by a separate flex cable) to each location memory 258 on each processing board 256. The location memory controller 262 communicates the spatial location information into each location memory 258 for each receive aperture processed by the signal processors 260 on the processing boards 256. The digital signal lines 273 may include, for example, a clock line for each processing board 256, a serial command data line for each processing board 256, two data lines (for a total of fourteen data lines) connected to each processing board 256, an output enable for one or more of the signal processors 260, and a test signal.

The location memory controller 262 communicates with the host system 266 over the digital signal lines 273 that may form part of, for example, a synchronous serial port. To that end, the communication interface 264 and digital signal lines 273 may implement a low voltage differential signal interface, for example, including a coaxial cable with a grounded shield and center signal wire. The location memory controller 262 includes a block of cache memory 275, for example, 1-8 MBytes of static random access memory (SRAM).

However, and as noted above, the various embodiments are not limited to use in connection with an ultrasound system or any medical imaging system. The various embodiments may be implemented in connection with any system that includes electronic components, such as electronic circuit boards.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112, sixth paragraph, unless and until such claim limitations expressly use the phrase “means for” followed by a statement of function void of further structure.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An electronic circuit board comprising:
a substrate; and
at least one integrated channel within the substrate configured to allow fluid flow therethrough.

2. An electronic circuit board in accordance with claim 1 wherein the integrated channel comprises at least one cavity.

3. An electronic circuit board in accordance with claim 1 further comprising a plurality of ports configured to allow access to the integrated channel.

4. An electronic circuit board in accordance with claim 3 further comprising at least one via connecting the plurality of ports to the integrated channel.

5. An electronic circuit board in accordance with claim 1 wherein the substrate is configured to connect to an electronic component mounted to a top surface of the substrate.

6. An electronic circuit board in accordance with claim 5 wherein the electronic component comprises at least one pin thermally connected to the integrated channel through a via in the substrate.

7. An electronic circuit board in accordance with claim 6 wherein the via is configured to provide electrical connection of the electronic component through the pin to an electrical layer of the substrate.

8. An electronic circuit board in accordance with claim 1 wherein the substrate comprises a plurality of layers.

9. An electronic circuit board in accordance with claim 8 wherein the integrated channel is formed from a cavity in one layer of the plurality of layers.

10. An electronic circuit board in accordance with claim 8 wherein the integrated channel is formed from cavities in more than one layer of the plurality of layers.

11. An electronic circuit board in accordance with claim 8 further comprising a via formed in more than one layer of the plurality of layers.

12. An electronic circuit board in accordance with claim 1 wherein the integrated channel comprises a plurality of different cavities.

13. An electronic circuit board in accordance with claim 1 wherein the substrate comprises a Low Temperature Co-fired Ceramics (LTCC) structure.

14. An electronic system having integrated cooling, the electronic system comprising:
a plurality of electronic circuit boards each having at least one cavity formed therein; and
at least one inlet port and at least one outlet port together configured to provide access to the at least one cavity in each of the plurality of circuit boards.

15. An electronic system in accordance with claim 14 wherein the at least one inlet port and the at least one outlet port are provided on at least one of the plurality of electronic circuit boards.

16. An electronic system in accordance with claim 14 further comprising an interface connected to the plurality of electronic circuit boards and wherein the at least one inlet port and the at least one outlet port are provided as part of the interface.

17. An electronic system in accordance with claim 14 wherein the at least one cavity forms an integrated channel.

18. An electronic system in accordance with claim 14 wherein the at least one cavity of each of the plurality of electronic circuit boards are connected is series.

19. An electronic system in accordance with claim 14 wherein the at least one cavity of each of the plurality of electronic circuit boards are connected is parallel.

20. A method for dissipating heat in an electronic circuit board, the method comprising:
forming at least one integrated channel within the electronic circuit board; and
providing access to the integrated channel from outside the electronic circuit board to allow fluid flow through the integrated channel.
